(19) United States
(12) Patent Application Publication
(10) Pub. No.: US 2025/0060415 A1
(43) Pub. Date: Feb. 20, 2025

(54) SYSTEM AND METHOD FOR ARCING AND IONIZATION DETECTION IN BATTERIES

(71) Applicant: SAMSUNG SDI CO., LTD., Yongin-si (KR)

(72) Inventors: Florian MAXL, Graz (AT); Eymen IPEK, Graz (AT)

(21) Appl. No.: 18/765,162

(22) Filed: Jul. 5, 2024

(30) Foreign Application Priority Data
Aug. 16, 2023 (EP) 23191722.0

(51) Int. Cl. G01R 31/3842; G01R 31/371

(52) U.S. Cl. CPC G01R 31/3842; G01R 31/371

(57) ABSTRACT

The present disclosure refers to a method for detecting the occurrence of a dielectric breakdown in a battery module. The present disclosure further refers to a method for disconnecting a battery module from a load upon detection of a dielectric breakdown in a battery module. Also, the present disclosure is related to a battery system with a battery module, the battery system being configured to perform the disclosed method for detecting the occurrence of a dielectric breakdown in a battery module and/or being configured to perform the disclosed method for disconnecting a battery module from a load upon detection of a dielectric breakdown in a battery module. Also, the present disclosure is related to a vehicle comprising at least one battery system according to the disclosure.

### CROSS REFERENCE TO RELATED APPLICATION

The present application claims priority to and the benefit of European Patent Application No. 23191722.0, filed on Aug. 16, 2023, in the European Intellectual Property Office, the entire disclosure of which is incorporated herein by reference.

### BACKGROUND

### 1. Field

The present disclosure relates to a battery system and method for detecting a dielectric breakdown in a battery module, and for disconnecting the battery module from a load thereupon, and to a vehicle including the battery system.

### 2. Description of the Related Art

In the recent years, vehicles for transportation of goods and peoples have been developed using electric power as a source for motion. Such an electric vehicle is an automobile that is propelled by an electric motor, using energy stored in rechargeable batteries. An electric vehicle may be solely powered by batteries or may be a form of hybrid vehicle powered by for example a gasoline generator or a hydrogen fuel power cell. Furthermore, the vehicle may include a combination of an electric motor and conventional combustion engine.

In general, an electric-vehicle battery (EVB) or traction battery is a battery used to power the propulsion of battery electric vehicles (BEVs). Electric-vehicle batteries differ from starting, lighting, and ignition batteries because they are designed to give power over sustained periods of time. A rechargeable or secondary battery differs from a primary battery in that it can be repeatedly charged and discharged, while the latter provides only an irreversible conversion of chemical to electrical energy. Low-capacity rechargeable batteries may be used as a power supply for small electronic devices, such as cellular phones, notebook computers and camcorders, while high-capacity rechargeable batteries may be used as a power supply for electric and hybrid vehicles and the like.

In general, rechargeable batteries include an electrode assembly including a positive electrode, a negative electrode, and a separator interposed between the positive and negative electrodes, a case receiving the electrode assembly, and an electrode terminal electrically connected to the electrode assembly. An electrolyte solution is injected into the case to enable charging and discharging of the battery via an electrochemical reaction of the positive electrode, the negative electrode, and the electrolyte solution. The shape of the case (e.g., cylindrical or rectangular) may depend on the battery's intended purpose. Lithium-ion (and similar lithium polymer) batteries, widely known via their use in laptops and consumer electronics, dominate the most recent group of electric vehicles in development.

Rechargeable batteries may be used as a battery module formed of a plurality of unit battery cells coupled in series and/or in parallel so as to provide a high energy content, for example, for motor driving of a hybrid vehicle. That is, the battery module is formed by interconnecting the electrode terminals of the plurality of unit battery cells depending on a suitable amount of power and to realize a high-power rechargeable battery.

Battery modules can be constructed either in block design or in modular design. In block designs each battery is coupled to a common current collector structure and a common battery management system and the unit thereof is arranged in a housing. In modular designs, pluralities of battery cells are connected to form submodules, and several submodules are connected to form the battery module. In automotive applications, battery systems often consist of a plurality of battery modules connected in series for providing a desired voltage. The battery modules may include submodules with a plurality of stacked battery cells, and each stack including cells connected in parallel that are connected in series (XpYs) or cells connected in series that are connected in parallel (XsYp).

A battery pack is a set of any number of (usually identical) battery modules. The battery modules may be configured in a series, parallel, or a mixture of both to deliver the desired voltage, capacity, or power density. Components of battery packs include the individual battery modules, and the interconnects, which provide electrical conductivity between the battery modules.

A battery system further includes a battery management system (BMS), which is any electronic system that manages the rechargeable battery, battery module and battery pack, such as by protecting the batteries from operating outside their safe operating area, monitoring their states, calculating secondary data, reporting that data, controlling its environment, authenticating it and/or balancing it. For example, the BMS may monitor the state of the battery as represented by voltage (such as total voltage of the battery pack or battery modules, voltages of individual cells), temperature (such as average temperature of the battery pack or battery modules, coolant intake temperature, coolant output temperature, or temperatures of individual cells), coolant flow (such as flow rate, cooling liquid pressure), and current.

A BMS may calculate values based on the above items, such as minimum and maximum cell voltage, state of charge (SOC), or depth of discharge (DOD) to indicate the charge level of the battery, state of health (SOH; a variously-defined measurement of the remaining capacity of the battery as % of the original capacity), state of power (SOP; the amount of power available for a defined time interval given the current power usage, temperature and other conditions), state of safety (SOS), maximum charge current as a charge current limit (CCL), maximum discharge current as a discharge current limit (DCL), and internal impedance of a cell (to determine open circuit voltage).

The BMS may be centralized such that a single controller is connected to the battery cells through a multitude of wires. The BMS may be also distributed, wherein a BMS board is installed at each cell, with just a single communication cable between the battery and a controller. Or the BMS may be of modular construction including a few controllers, each handling a corresponding number of cells, with communication between the controllers. Centralized BMSs are, generally, most economical, least expandable, and are plagued by a multitude of wires. Distributed BMSs are, generally, the most expensive, simplest to install, and offer the cleanest assembly. Modular BMSs offer a compromise of the features and problems of the other two topologies.

A BMS may protect the battery pack from operating outside its safe operating area. Operation outside the safe operating area may be indicated if there is over-current, over-voltage (during charging), over-temperature, under-temperature, over-pressure, and ground fault or leakage current detection. The BMS may disable operation outside the battery's safe operating area by including an internal switch (such as a relay or solid-state device) that is opened if the battery is operated outside its safe operating area, by requesting the devices to which the battery is connected to reduce or even terminate using the battery, and by actively controlling the environment, such as through heaters, fans, air conditioning or liquid cooling.

For meeting the dynamic power usage of various electrical consumers connected to the battery system a static control of battery power output and charging is not sufficient. Thus, steady exchange of information between the battery system and the controllers of the electrical consumers is suitable. This information includes the battery systems actual state of charge, SoC, potential electrical performance, charging ability, and/or internal resistance, as well as actual or predicted power usage or surpluses of the consumers. Battery systems may include a battery management system, BMS, for obtaining and processing such information on system level and further a plurality of battery module managers (BMMs) which are part of the system's battery modules and obtain and process relevant information on module level. For example, the BMS usually measures the system voltage, the system current, the local temperature at different places inside the system housing, and the insulation resistance between live components and the system housing. The BMMs may measure the individual cell voltages and temperatures of the battery cells in a battery module.

Thus, the BMS/BMU is provided for managing the battery pack, such as by protecting the battery from operating outside a safe operating area, monitoring a state of the battery, calculating secondary data, reporting the secondary data, controlling the battery's environment, authenticating that battery, and/or balancing the battery.

If there is an abnormal operation state, a battery pack may be disconnected from a load connected to a terminal of the battery pack. Battery systems further include a battery disconnect unit, BDU, that is electrically connected between the battery module and battery system terminals. Thus, the BDU is the primary interface between the battery pack and the electrical system of the vehicle. The BDU includes electromechanical switches that open or close high current paths between the battery pack and the electrical system. The BDU provides feedback to the battery control unit, BCU, accompanied to the battery modules, such as voltage and current measurements. The BCU controls the switches in the BDU using low current paths based on the feedback received from the BDU. The main functions of the BDU may include controlling current flow between the battery pack and the electrical system and current sensing. The BDU may further manage additional functions like external charging and pre-charging.

A secondary battery cell, such as a lithium-ion battery cell, includes two electrodes located in an electrolyte solution. The electrodes are separated from each other by a separator made of an electrically insulating material (a so-called “dielectric”), which is, however, permeable for ions (e.g., Li⁺ ions in a lithium-ion battery) to allow these ions to freely move between these electrodes. However, if there is damage of the separator (e.g., damage caused by mechanical damaged to a mechanical impact on the battery cell or caused by an overload of the battery cell), the material of the separator may become ionized. Typically, a channel is then formed through the separator for a corresponding time, in which an electrically conductive plasma is created from the insulator material by heat and ionization. This situation is called a “dielectric breakdown.” In some situations, the dielectric breakdown may then continue to burn as an electric arc, causing an arc-fault of the affected battery cell.

Generally, automotive battery systems include voltage sources having a hazardous voltage level. Due to the nature of the application, dielectric breakdown caused by misuse or accident may happen, which may cause fire or explosion inside the battery system. For example, the dielectric breakdown or ionization inside of a battery system may cause short circuit or electric arcing. However, the arc may take a few seconds to take effect before it causes a damage.

There is a desire for a method and a battery system that allow for a fast detection of the occurrence of electric arcing within a battery module. Further, there is a desire for a method and a battery system allowing for disconnecting the battery module from a load upon detection of electric arcing inside the battery module. Also, there is a desire for a vehicle equipped with one of the afore-mentioned a battery system to increase the safety of use.

An aspect of the present disclosure provides a method and a battery system that allow for a fast detection of the occurrence of electric arcing within a battery module. Further, an aspect of the present disclosure presents a method and a battery system allowing for disconnecting the battery module from a load upon detection of electric arcing inside the battery module. Moreover, an aspect of the present disclosure provides a vehicle equipped with one of the afore-mentioned a battery system to increase the safety of use.

### SUMMARY

The present disclosure is defined by the appended claims. The description that follows is subjected to this limitation. Any disclosure lying outside the scope of said claims is only intended for illustrative as well as comparative purposes.

The present disclosure describes a method and a battery system that allow for a detection of an arcing potential within a battery module prior to the occurrence of any hazardous situation. Detection may be done by using existing measurements with an additional signal-conditioning circuit configured to analyze frequency spectrum of these measurements or, for example, signals generated based on these measurements.

Further aspects of the present disclosure could be learned from the dependent claims or the following description.

One of the aspects of the method and the battery system presented in the present disclosure is the capability to quickly detect unwanted developing ionization inside of the battery prior to catastrophic short circuit or arcing. For example, an ionization occurring within a battery module (e.g., in at least one of its battery cells) is recognized already during its initial phase such that a load can be electrically disconnected from the affected battery module before the battery module itself and/or the connected load would be damaged by a further continuing ionization processes within the battery module. By implementing a signal-conditioning circuit that analyzes frequency spectrum of suitable operation states of the battery module (such as current, voltage, or both), an ionization as well as an increasing conductivity path can be detected.

According to one or more embodiments, there is provided a method for detecting a dielectric breakdown in a battery module, the method including measuring at least one operation state of the battery module, generating at least one operation signal respectively corresponding to the at least one operation state, checking whether the at least one operation signal includes a pattern indicating a possible arc-fault within the battery module, and generating a warning signal upon detecting the at least one operation signal includes the pattern.

The at least one operation state may include a current generated by, or occurring in, the battery module, wherein generating the at least one operation signal includes generating a current signal based on the at least one operation state including the current, and wherein checking whether the at least one operation signal includes the pattern includes checking whether the current signal includes the pattern.

The at least one operation state may include a voltage generated by the battery module, or an electrical potential difference inside the battery module, wherein checking whether the at least one operation signal includes the pattern indicating the possible arc-fault includes checking whether the voltage signal includes the pattern.

Checking whether the at least one operation signal includes the pattern may include generating a frequency spectrum for the at least one operation signal including a current signal and/or the voltage signal, and comparing the frequency spectrum with a reference frequency spectrum.

Comparing the frequency spectrum with the reference frequency spectrum may include detecting, for at least one frequency value in the reference frequency spectrum, whether an amplitude of the frequency spectrum exceeds an amplitude of the reference frequency spectrum, wherein generating the warning signal is based upon detection that the amplitude of the frequency spectrum exceeds the amplitude of the reference frequency spectrum at the at least one frequency value.

Generating the frequency spectrum may include performing a Fourier transform of at least a part of the current signal and/or the voltage signal.

The method may further include storing amplitudes of the at least one operation signal for sample points in time within a time window, and performing a fast Fourier transform based on the sample points and the stored amplitudes.

Checking whether the at least one operation signal includes the pattern may include inputting the at least one operation signal to at least one bandpass filter, measuring an amplitude of a signal outputted from the bandpass filter, and comparing the amplitude of the signal outputted from the bandpass filter with a reference value, wherein the warning signal is based upon detecting the amplitude exceeds the reference value.

The method may further include disconnecting the battery module from a load in response to the warning signal.

According to one or more embodiments, there is provided a battery system including a battery module including at least one battery cell, a measurement device configured to measure at least one operation state of the battery module, and to generate at least one operation signal corresponding to the at least one operation state, and a control unit configured to receive the at least one operation signal from the measurement device, check whether the at least one operation signal includes a pattern indicating an occurrence of an arc-fault within the battery module, and generate a warning signal upon detection that the at least one operation signal includes the pattern.

The at least one operation state may include a current generated by, or occurring in, the battery module, wherein the measurement device includes a current sensor configured to measure the current, and configured to generate a current signal corresponding to the current and the at least one operation signal, and wherein the control unit is configured to check whether the current signal includes the pattern.

The at least one operation state may include a voltage generated by, or an electrical potential difference inside, the battery module, wherein the measurement device includes a voltage sensor configured to measure the voltage, and configured to generate a voltage signal corresponding to the voltage corresponding to the at least one operation signal, and wherein the control unit is configured to check whether the voltage signal includes the pattern.

The control unit may be configured to generate a frequency spectrum of the at least one operation signal corresponding to a current signal or the voltage signal, and to compare the frequency spectrum with a reference frequency spectrum.

The battery system may further include a first terminal connected via a first electrical line to the at least one battery cell, a second terminal connected via a second electrical line to the at least one battery cell, a first switch configured to interrupt the first electrical line upon receiving a first interruption signal, and a second switch configured to interrupt the second electrical line upon receiving a second interruption signal, wherein the control unit is configured to send the first interruption signal, and/or send the second interruption signal, based upon the warning signal.

According to one or more embodiments, there is provided a vehicle including the battery system.

### BRIEF DESCRIPTION OF THE DRAWINGS

Aspects will become apparent to those of ordinary skill in the art by describing in detail embodiments with reference to the attached drawings in which:

FIG. 1 is a schematic three-dimensional view of a battery module.

FIG. 2 is a block diagram schematically illustrating an aspect of operation of one or more embodiments of the method.

FIG. 3 schematically illustrates current measurements during normal operation and during arcing.

FIG. 4 schematically illustrates an extraction of amplitude values of current during arcing in time domain (A) and in frequency domain (B).

FIGS. 5A, 5B, and 5C schematically illustrate several different embodiments of a battery system according to the present disclosure.

FIG. 6 illustrates schematically the spectral analysis of an incoming signal using an analog circuit.

### DETAILED DESCRIPTION

Reference will now be made in detail to embodiments, examples of which are illustrated in the accompanying drawings. Aspects of the embodiments, and implementation methods thereof will be described with reference to the accompanying drawings. In the drawings, like reference numerals denote like elements, and redundant descriptions are omitted. The present disclosure, however, may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art.

Accordingly, processes, elements, and techniques that are not considered necessary to those having ordinary skill in the art for a complete understanding of the aspects of the present disclosure may not be described. In the drawings, the relative sizes of elements, layers, and regions may be exaggerated for clarity.

As used herein, the term “and/or” includes any and all combinations of one or more of the associated listed items. Further, the use of “may” when describing embodiments of the present disclosure refers to “one or more embodiments of the present disclosure.” In the following description of embodiments of the present disclosure, the terms of a singular form may include plural forms unless the context clearly indicates otherwise.

It will be understood that although the terms “first” and “second” are used to describe various elements, these elements should not be limited by these terms. These terms are only used to distinguish one element from another element. For example, a first element may be named a second element and, similarly, a second element may be named a first element, without departing from the scope of the present disclosure. As used herein, the term “and/or” includes any and all combinations of one or more of the associated listed items. Expressions, such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent deviations in measured or calculated values that would be recognized by those of ordinary skill in the art. Further, if the term “substantially” is used in combination with a feature that could be expressed using a numeric value, the term “substantially” denotes a range of +/−5% of the value centered on the value.

It will be further understood that the terms “include,” “include,” “including,” or “including” specify a property, a region, a fixed number, a step, a process, an element, a component, and a combination thereof but do not exclude other properties, regions, fixed numbers, steps, processes, elements, components, and combinations thereof.

Herein, the terms “upper” and “lower” are defined according to the z-axis. For example, the upper cover is positioned at the upper part of the z-axis, whereas the lower cover is positioned at the lower part thereof. In the drawings, the sizes of elements may be exaggerated for clarity. For example, in the drawings, the size or thickness of each element may be arbitrarily shown for illustrative purposes, and thus the embodiments of the present disclosure should not be construed as being limited thereto.

In the following description of embodiments of the present disclosure, the terms of a singular form may include plural forms unless the context clearly indicates otherwise.

The electronic or electric devices and/or any other relevant devices or components according to embodiments of the present disclosure described herein may be implemented utilizing any suitable hardware, firmware (e.g., an application-specific integrated circuit), software, or a combination of software, firmware, and hardware. Further, the various components of these devices may be implemented on a flexible printed circuit film, a tape carrier package (TCP), a printed circuit board (PCB), or formed on one substrate. The electrical connections or interconnections described herein may be realized by wires or conducting elements, e.g., on a PCB or another kind of circuit carrier. The conducting elements may include metallization, e.g., surface metallizations and/or pins, and/or may include conductive polymers or ceramics. Further electrical energy might be transmitted via wireless connections, e.g. using electromagnetic radiation and/or light.

Further, the various components of these devices may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like.

Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

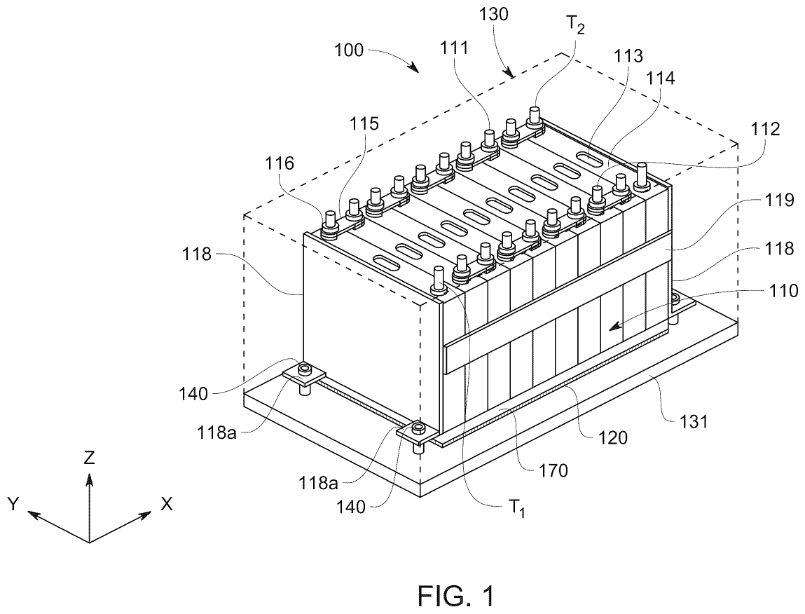

FIG. 1 is a schematic three-dimensional view of a battery module. Referring to FIG. 1, one or more embodiments of a conventional battery module 100 includes a plurality of battery cells 110 aligned in one direction (e.g., the x-direction with reference to FIG. 1). A heat exchange member 170 may also be provided adjacent to a bottom surface of the plurality of battery cells 110. Further, a pair of end plates 118 are provided to face wide surfaces of the battery cells 110 at the outside of the battery cells 110, and a connection plate 119 is configured to connect the pair of end plates 118 to each other, thereby also fixing the plurality of battery cells 110 together. Fastening portions 118a on both sides of the battery module 100 are fastened to a support plate 131 by bolts 140. The support plate 131 is part of a housing 130.

In one or more embodiments, each battery cell 110 is a generally prismatic or generally cuboidal-shaped cell, the wide flat surfaces of the cells being stacked together to form the battery module. Further, each battery cell 110 includes a battery case configured for accommodation of an electrode assembly and an electrolyte. The battery case is hermetically sealed by a cap assembly 114. The cap assembly 114 is provided with positive and negative electrode terminals 111 and 112 having different polarities, and a vent 113.

The positive electrode T₁ of the first battery cell (when viewed along the x-axis) forms the positive terminal of the battery cell stack. Correspondingly, the negative electrode T₂ of the last battery cell (when viewed along the x-axis) forms the negative terminal of the battery cell stack. As the illustrated battery module 100 only includes a single battery cell stack, the terminal T₁ at the same time forms the positive electrode of the complete battery module 100, and the terminal T₂ at the same time forms the negative electrode of the complete battery module 100.

The vent 113 is a safety device of the battery cell 110, which acts as a passage through which gas generated in the battery cell 110 is exhausted to the outside of the battery cell 110. The positive and negative electrode terminals 111 and 112 of neighboring battery cells 110 are electrically connected through a bus bar 115, and the bus bar 115 may be fixed by a nut 116 or the like. In one or more embodiments, the battery module 100 may be used as power source unit by electrically connecting the plurality of battery cells 110 as one bundle.

The battery cells 110 may generate a large amount of heat while being charged/discharged. The generated heat is accumulated in the battery cells 110, thereby accelerating the deterioration of the battery cells 110. In one or more embodiments, the battery module 100 further includes a heat exchange member 170, which is provided adjacent to the bottom surface of the battery cells 110 so as to cool down the battery cells 110. In one or more embodiments, an elastic member 120 made of rubber or other elastic materials may be interposed between the support plate 131 and the heat exchange member 170.

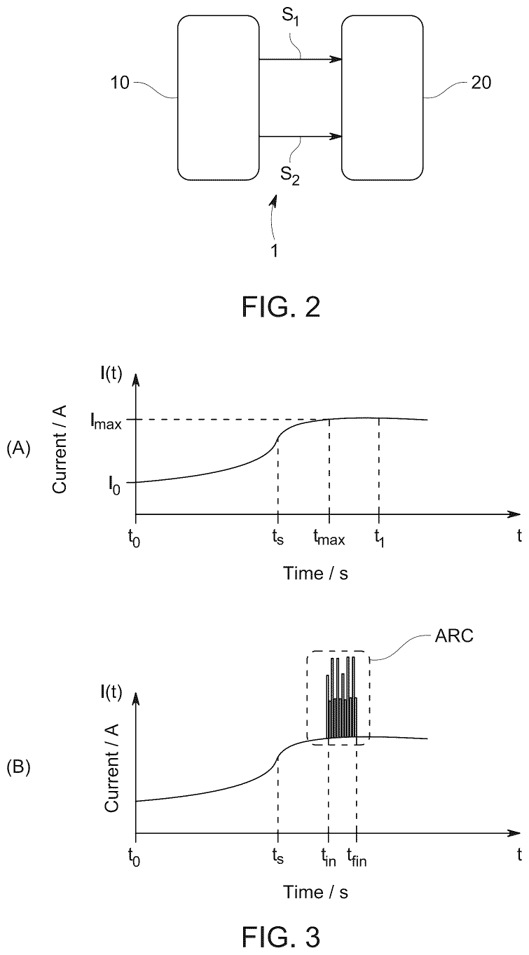

FIG. 2 is a block diagram schematically illustrating an operational aspect of one or more embodiments of the method for detecting the occurrence of a dielectric breakdown in a battery module according to the present disclosure, as well as a corresponding battery system. For example, the diagram illustrates a battery system 1 according to the present disclosure, which includes a battery module 10 and a control unit 20. The battery module 10 includes a plurality of battery cells. The battery cells may be arranged in at least one battery cell stack. For example, the battery module 10 may correspond to the battery module 100 as shown in FIG. 1. However, it is understood that other internal arrangements of the battery cells (e.g., configurations) can also be used inside of the battery module 10, wherein the battery module 10 includes a plurality of battery cell stacks.

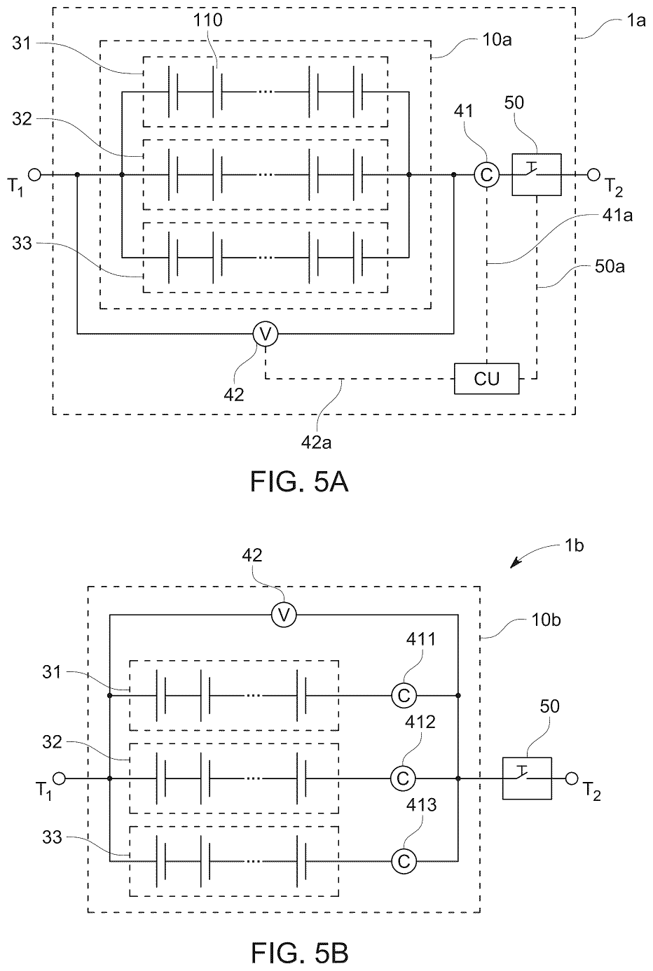

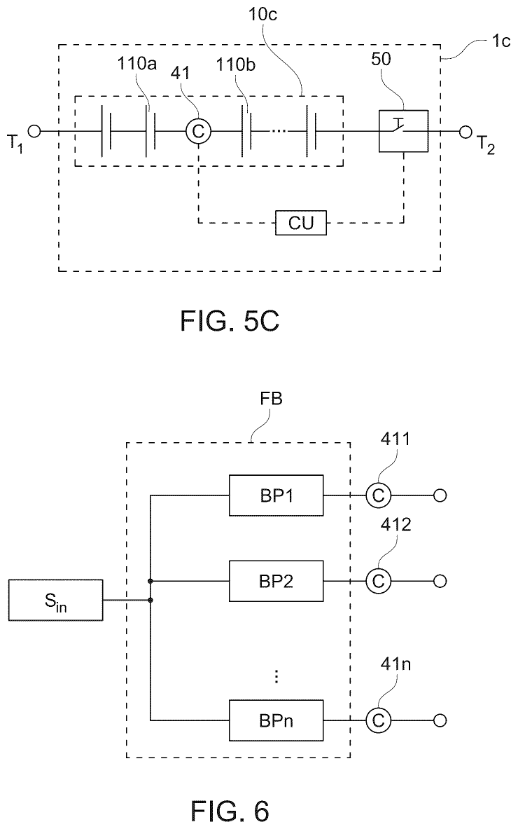

In the one or more embodiments of the battery system 1 corresponding to FIG. 2, the battery system 1 is configured to monitor two different operation states of the battery module 10, such as a current generated by the battery module 10 and the voltage generated by the battery module 10. In one or more embodiments, a measurement device having respective sensors may be implemented into the battery system 1, the sensors each being configured for measuring one of the operation states to be measured. Because a current and a voltage generated by the battery module 10 are to be measured, the measurement device of the battery system 1 includes a current sensor 41 as well as a voltage sensor 42 (e.g., see FIGS. 5A, 5B, and 5C). If, for example, the battery module 10 corresponds to the battery module 100 illustrated in FIG. 1, the current sensor 41 may be arranged in series with the battery cell stack depicted in FIG. 1 (e.g., either electrically connected to the first terminal T₁ or electrically connected to the second terminal T₂ of the depicted battery cell stack). Also, the voltage sensor 42 may be arranged in parallel to the depicted battery cell stack (e.g., electrically connected with both, the first terminal T₁ and the second terminal T₂). However, for example, if the battery module 10 internally is assembled different from the assembly of the battery module 100 of FIG. 1, the current sensor 41 and/or the voltage sensor 42 may be arranged otherwise within the battery module 10. This will be explained in more detail below with reference to FIG. 5.

Each of the sensors generates a signal (operation signal) corresponding to the operation state of the battery module 10 measured by the sensor. In the example of FIG. 2, the current sensor 41 generates an operation signal corresponding to the measured current (this operation signal in the following referred to as current signal), and the voltage sensor 42 generates an operation signal corresponding to the measured voltage (the latter operation signal in the following referred to as voltage signal). Further, the control unit 20 is configured to receive each of the operation signals generated by the sensors of the measurement device. In one or more embodiments, the control unit 20 is configured to receive the current signal S₁ from the current sensor 41 and to receive the voltage signal S₂ from the voltage sensor 42.

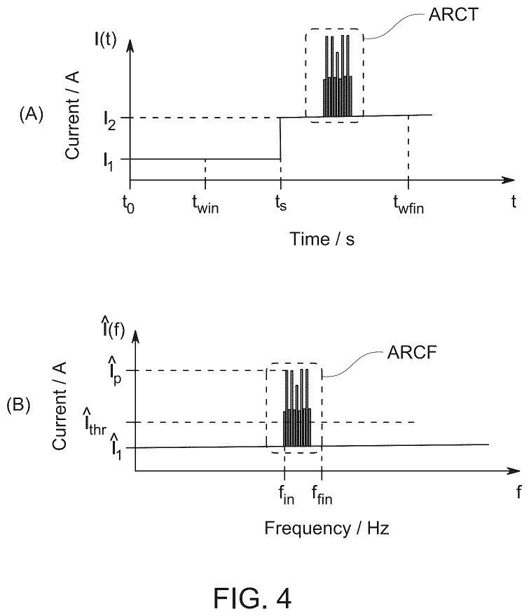

Further, the control unit 20 is configured for evaluating the received operation signals, and, for example, for detecting whether at least one of these operation signals exhibits a pattern indicating and arc-fault occurring within the battery module 10 (e.g., in at least one of the battery cells included in the battery module 10). The afore-mentioned evaluation of the received operation signals and detection of patterns indicating a possible arc-fault will be described in more detail with the help of the following FIGS. 3 and 4.

Automotive battery systems generally provide or accept continuously changing currents. However, as the electrically connected systems (loads) have each a corresponding inductance, the current usage and/or the current supply does usually not change abruptly (e.g., in a discontinuous way with respect to time), but generally changes only within a corresponding window. The change of the intensity of current (amperage) with respect to time generally does not exceed a defined level of derivation, or equivalently, using a formula, when the intensity of the current is expressed as a function I(t) of the time t, it holds |dI(t)/dt|≤c with c>0 and being a known constant.

This is illustrated schematically in the diagram of FIG. 3(A) showing a course of an intensity of current (the diagram's ordinate) provided by a battery module as a function over the time t (abscissa of the diagram). As indicated in the diagram, the current may be measured in amperes (A), and the time may be given in seconds(s), noting that the diagram is only illustrative. For example, the value of the intensity of current is I₀ at the point in time t₀. At time t₀, the usage of current suitable for a load connected to the battery module may increase. The current provided by the battery module increases until it reaches a maximum value Iₘₐₓ at the time tₘₐₓ, where Iₘₐₓ may correspond to the current supply suitable for the load.

However, as can be taken from the diagram, the current supplied by the battery module is not increased constantly (e.g., the function I(t) is not linear in the range between t₀ and tₛ). Rather, when starting at to, the current at first only slightly increases, and then, the increase occurs more quickly until the current increase reaches its maximum value at the time tₛ. After the point in time tₛ, the increase of the current is slowed down again before the current reaches its maximum value at tₘₐₓ. After the time tₘₐₓ, the intensity of current remains approximately constant (see the region around the time t₁). However, as can be taken from FIG. 3(A), the (absolute value of the) change |dI(t)/dt| of the intensity of the current I(t) (e.g., the slope of the graph depicted in the diagram) does not exceed the value of the slope at the time tₛ.

While FIG. 3(A) illustrates the course of a current with respect to time when the battery module is in a normal state of operation, the course of the current will be significantly different from that when an arc-fault occurs within at least one of the battery cells of the battery module. This is schematically illustrated in FIG. 3(B), showing generally the same diagram as FIG. 3(A), with the difference, however, that an arc-fault event occurs in the battery module. If there is arcing, the intensity of the current changes extremely quickly within a short period of time. This is schematically illustrated in FIG. 3(B) by the behavior of the graph shown in the region ARC (between the points in time tᵢₙ and t_{fin}), where the function I(t) changes very quickly (in comparison to the normal behavior of the function as illustrated in FIG. 3(A)) between various rather different values of the intensity of current. In the event of arcing, the derivative of the intensity of current with respect to time by far exceeds the maximum value of the derivative that could be reached if there is a normal operation of the battery module as explained above. In one or more embodiments, for corresponding times t, absolute derivative values |dI(t)/dt|>c will occur during arcing with c>0 being the above-explained maximum boundary for the absolute values of the derivative of the intensity of current with respect to time.

However, as already indicated above with respect to the region ARC in the diagram of FIG. 3(B), not only a single abrupt change of the intensity of current is experienced if there is arcing but also a very fast change between higher and lower values of the intensity current. In one or more embodiments, the arcing current is not regulated and occurs without (approximately) linear increment. Consequently, when looking at a spectral representation of the intensity of current as a function over time, as shown in FIG. 3(B), there will be frequencies with a significant amplitude, these frequencies corresponding to the fast changes of the current caused by the arcing as described before. For example, frequencies indicative for arcing may occur in a corresponding frequency around 100 kHz. In one or more embodiments, in the event of an arc-fault in the battery module, a frequency representation of the intensity of current will include exhibit very high amplitudes for frequencies being caused by, or associated with, arcing. In one or more embodiments, an arcing event can be detected by filtering noise, adding data window based search and observing corresponding patterns in the frequency spectrum.

FIG. 4(A) is a diagram similar to that of FIG. 3(B). For example, the intensity of a current (ordinate of the diagram) supplied by a battery module is schematically illustrated by a function over time (abscissa of the diagram). The actual current usage of the load connected to the battery module is indicated by the straight horizontal lines (corresponding current intensities of I₁ and I₂, respectively) of the curve depicted in FIG. 4(A). At the beginning with time to, the load of the battery module may be caused by a corresponding device electrically connected to the battery, wherein the device uses a constant current supply.

Then, at the point in time tₛ, a further device may be switched on such that the usage of the load becomes relatively quickly increased at this time tₛ, which is indicated by a step of the depicted curve at the time tₛ, although the step may show a flattened shape with a maximum derivative not exceeding a corresponding boundary value, as explained before in the context of FIG. 3. After the time tₛ, a high-frequency change in the course of the intensity of current is experienced (indicated in the diagram by the region ARCT), which may be indicative to an arc-fault event occurring in the battery module.

The diagram of FIG. 4(B) schematically illustrates a spectral representation of the intensity of current as shown in the diagram of FIG. 4(A). The function in the diagram of FIG. 4(B) may be obtained by a Fourier transform of the function illustrated in FIG. 4(A). While the intensity of current is represented in FIG. 4(A) as a function I(t) over time t (e.g., over the “time domain”), the intensity of current is represented in FIG. 4(B) as a function Î(f) over the frequency f (e.g., over the “frequency domain”). As only the (absolute values of the) amplitudes Î(f) of the frequencies f are shown in FIG. 4(B), the diagram of FIG. 4(B) may not be fully equivalent to the diagram of FIG. 4(A), because the phases are omitted in FIG. 4(B). FIG. 4(A) and FIG. 4(B) are merely illustrative, and, for example, the function Î(f) shown in FIG. 4(B) may not be an exact spectral representation of the function I(t) of FIG. 4(A).

The spectral analysis to generate the diagram of FIG. 4(B) based on the information provided in the diagram of FIG. 4(A) may have been performed using the data in the time-window between t_{win} and t_{wfin}, including the point in time tₛ. Due to the sudden step-like increase of the intensity of current appearance in the time domain at the time tₛ (see FIG. 4(A)), the spectral representation exhibits a corresponding minimum amplitude Î₁ for all frequencies f in the illustrated frequency range. For example, with a flattened step of the intensity of current in the time domain, as described above, this “background” might not be constant over the frequency domain, and instead may be slightly decreasing as the frequency f increases.

Also, other shapes of the amplitudes Î(f) of the shown spectral representation as a function of the frequency f are possible. However, during normal operation of the battery module, the amplitudes Î(f) are each bounded by a corresponding maximum value Îₘₐₓ(f), which may be frequency-dependent (e.g., may be given as a function of the frequency f). In the example of FIG. 4(B), it may be set Îₘₐₓ(f)=Î₁=const. However, in general, the boundary for the maximum value of an amplitude during normal operation of the battery module may depend on the frequency f (e.g., there may be a boundary function Îₘₐₓ(f)>0 such that it holds Î(f)≤Îₘₐₓ(f) for all frequencies, or at least for each frequency f within a relevant frequency range).

However, as can be seen from FIG. 4(B), this is not the case for the function shown in the diagram of FIG. 4(B). Rather, in a frequency range between fᵢₙ and f_{fin}, the amplitudes Î(f) of the shown spectral representation Î(f) as a function of the frequency f show fierce changes in close density (see the region indicated as ARCF in FIG. 4(B)), which may be considered as analogous of the behavior of the intensity of current I(t) in the region ARCT when viewed in the time domain (see FIG. 4(A)). For example, in the region ARCF, there are frequencies having an amplitude by far larger than that of the “background” amplitude Î₁ in the present example. The relation Î(f)≤Îₘₐₓ(f)=Î₁ no longer holds in the illustrated example, because there are frequency values f having an amplitude Î(f)>Î₁. In one or more embodiments, the noise in the region ARCT of the diagram of FIG. 4(A) (showing the intensity of current with respect to the time domain) can be detected simply by checking, with respect to the spectral representation of the intensity of current, whether the relation Î(f)≤Îₘₐₓ(f) is infringed for at least some frequency values f being caused by, or associated with, arcing, or, equivalently, whether the relation Î(f)≤Îₘₐₓ(f) holds at least for some frequency values f caused by, or associated with, arcing.

However, due to natural or usual variations in the frequency that may occur without an arc-fault event being present, using the relation Î(f)≤Îₘₐₓ(f) for the detection of arc-faults may be too sensitive a check, resulting in an increased likelihood of false-positive detections of arc-faults and/or false alarms. In one or more other embodiments, to avoid excessive sensitivity, it may be checked whether the relation Î(f)≤Îₜₕᵣ(f) is infringed with a threshold amplitude (e.g., predefined threshold amplitude) Îₜₕᵣ(f), which may also be frequency-dependent (e.g., may be given as a function of the frequency f), wherein Îₘₐₓ(f)<Îₜₕᵣ(f) for all frequencies f in a relevant frequency range, while at the same time, Îₜₕᵣ(f) is chosen smaller than peaks (e.g., typical or expected peaks) in the amplitudes of the spectral representation of the current intensity during an arc-fault event. This is schematically illustrated in the example of FIG. 4(B) by a (constant) threshold amplitude Îₜₕᵣ with Îₘₐₓ(f)=Î₁<Îₜₕᵣ<Î_{P}, where Î_{P} denotes a value of peaks of the amplitude of the spectral representation of the intensity of current Î(f) if there is an arc-fault event.

In one or more embodiments, one of the afore-described checks (e.g., with the notations as defined above, the check of whether the relation Î(f)≤Îₘₐₓ(f) is infringed, or the check whether the relation Î(f)≤Îₜₕᵣ(f) is infringed) may be implemented in embodiments of the method for detecting the occurrence of a dielectric breakdown in a battery module. In such embodiments, at least one of the measured operational states of the battery module is a current measured by a current sensor 41 within the battery module, and the operation signal is a current signal generated by the current sensor 41, or at least the signal equivalent to the current signal (e.g., the original current signal multiplied by a corresponding constant factor for the sake of scaling etc.).

In one or more embodiments, also other operation states of a battery module may be measured and checked in a similar way in one or more other embodiments of the method according to the present disclosure. For example, a measured voltage may be used instead of a measured current in one or more other embodiments of the present disclosure. In one or more embodiments, a voltage as well as a current is measured in the battery module, and two operation states of the battery module (e.g., the measured voltage and the measured current) become monitored and checked during the operation of the battery module.

The monitoring of the operation states can be performed permanently (e.g., continuously for each time t in the time domain). In one or more other embodiments, checks are only performed repeatedly for discrete points within the time domain. It may be suitable that a monitored operation state of the battery module (such as a current and/or a voltage) is measured for a corresponding time-window of the length (e.g., predefined length) to transform the measurement into a spectral representation.

To be able to perform the afore-described check upon the operation signals (e.g., a current and/or voltage measured within the battery module), the control unit may be configured such that a transform of the time-dependent input signal based on a measured operation state into a spectral representation can be done. In embodiments, this may be done digitally (e.g., by storing the values of an input operation signal, such as a current signal and/or a voltage signal) for a time duration (e.g., predefined time duration) ΔT, and may be done by subsequently using the stored values as input for a Fourier transform performed by a CPU or microcontroller. In one or more other embodiments, a spectral representation of the input signal may be performed by analog technology, such as a filter bank, as will be described in more detail below with reference to FIG. 6.

FIGS. 5A, 5B, and 5C schematically illustrates several different embodiments of a battery system according to the present disclosure. For example, FIG. 5A illustrates a battery system 1a including a battery module 10a with three battery cell stacks 31, 32, 33. Each of the battery cell stacks 31,32, 33 includes a plurality of battery cells 110. In the example of FIG. 5A, the three battery cell stacks 31, 32, 33 are electrically connected in parallel. Connected in series to the battery module 10a (e.g., to the ensemble of the three battery cell stacks 31, 32, 33 being connected in parallel) is a current sensor 41. Further, a voltage sensor 42 is connected in parallel to the battery module 10a. In one or more embodiments, if at least one of the battery cells 110 included in the battery module 10a (e.g., in one of the battery cell stacks 31, 32, 33) undergoes a developing ionization in conjunction with electric arcing, the above-described effects of high-frequent changes in current, as well as in voltage, may superimpose to the current and voltage generated by the complete assembly of the three battery cell stacks 31, 32, 33, and then may be measured by both the current sensor 41 and the voltage sensor 42.

As a result of these measurements, operation signals are then transmitted to the control unit CU of the battery system 1a. For example, a current signal is transferred via a first signal line 41a to the control unit CU, and a voltage signal is transferred via a second signal line 42a to the control unit CU. Then, the control unit CU evaluates these operation signals by the method as described before with reference to FIGS. 3 and 4. For example, the control unit CU checks the incoming operation signals on patterns that may indicate arcing inside the battery module 10a. Upon detection of such a pattern, the control unit CU generates a warning signal that is used, in the illustrated example, to operate the switch 50 so as to disconnect the battery module 10a from a load, which may be connected to the battery module 10a by the terminals T₁, T₂. In one or more other embodiments, a further switch may be provided between the battery module 10a and the first terminal T₁, the further switch 50 operated analogously to the shown switch 50 by the control unit CU. Then, both terminals T₁, T₂ of the battery module 10a will be disconnected upon detection of an arc-fault inside the battery module 10a.

One or more other embodiments of a battery system 1b according to the present disclosure correspond to FIG. 5B. As in the example of FIG. 5A, the battery system 1b includes a battery module 10b equipped with three battery cell stacks 31, 32, 33 connected in parallel to each other. However, in one or more embodiments, the operation states used for checking on occurring arc-faults inside the battery module 10b are measured differently in comparison to the example of FIG. 1A. For example, the intensity of current as well as the voltage are measured in the illustrated example individually for each of the battery cell stacks 31, 32, 33. For example, a first current sensor 411 is connected in series with the first battery cell stack 31, and correspondingly, a second current sensor 412 and a third current sensor 413 are connected in series with the second battery cell stack 32 and the third battery cell stack 33, respectively. Furthermore, a voltage sensor 42 is installed in parallel to the assembly of battery cell stacks 31, 32, 33, which is comparable to the arrangement of the voltage sensor 42 in the example of FIG. 5A.

In one or more embodiments, in the example of FIG. 5B, the current generated by each of the battery cell stacks 31, 32, 33 can be measured individually such that, if there is the occurrence of an arc-fault inside the battery module 10a, it could be detected, which of the battery cell stacks 31, 32, 33 contains the battery cell affected by the arc-fault.

Each of the current sensors 411, 412, 413 and the voltage sensor 42 is connected via the respective signal line to a control unit. For the sake of simplicity, the control unit and the signal lines are not shown in FIG. 5B. Again, the control unit is configured to evaluate the operation signals by the method as described before with reference to FIGS. 3 and 4, and to generate a warning signal that is used, in the illustrated example, to operate the switch 50 so as to disconnect the battery module 10b from a load, which may be connected to the battery module 10b by the terminals T₁, T₂. Again, a second switch operated in a similar way as the shown switch 50 may be implemented in embodiments to disconnect the battery module 10b from the second terminal T₂.

Further, FIG. 5C illustrates schematically a further possibility to arrange an operational sensor inside the battery module. For example, one or more other embodiments of the battery system 1c includes a battery module 10c having only a single battery cell stack. For example, the battery module 10c may correspond to the battery module 100 shown in FIG. 1. In the example, the current sensor 41 is not connected in series with the battery module 10c, but rather arranged inside the stack of battery cells of the battery module 10c between two adjacent battery cells 110a and 110b. The signal produced by the current sensor 41 is transmitted to the control unit CU being configured to operate the switch 50 so as to disconnect the battery module 10c from a load, which may be connected to the battery module 10c via the terminals T₁, T₂, upon detection of an arc-fault inside the battery module 10c.

FIG. 6 illustrates schematically how to perform the spectral analysis of an incoming signal Sᵢₙ using an analog circuit. The input signal Sᵢₙ may be one of the operation signals generated by measurement device/measurement sensors of embodiments of the battery system according to the present disclosure. Here, an input signal Sᵢₙ becomes inputted to a filter bank FB including a plurality of bandpass filters BP1, BP2, . . . , BPn. The passing ranges of the bandpass filters BP1, BP2, . . . , BPn may be pairwise disjunct in embodiments of the depicted analytics circuit. However, in embodiments, the passing ranges of the bandpass filters BP1, BP2, . . . , BPn may partially overlap. Then, the first bandpass filter BP1 passes frequencies within a corresponding range around the first frequency, the second bandpass filter BP2 passes frequencies within a corresponding range around second frequency unlike to the first frequency, etc. Subsequently, the amplitudes of the signals having passed the bandpass filters BP1, BP2, . . . , BPn are measured by respective current sensors 411, 412, . . . , 41n. This way, at least an approximation of the spectral representation of the incoming input signal Sᵢₙ is generated by the circuit depicted in FIG. 6. The circuit of FIG. 6 may be used in embodiments of the battery system according to the present disclosure to generate a spectral representation of an operation signal.

Description of Some of the Reference Characters

| | |
|---|---|
| 1: battery system | 1a, 1b, 1c: battery systems |
| 10: battery module | 10a, 10b, 10c: battery modules |
| 20: control unit | 31, 32, 33: battery cell stacks |
| 41: current sensor | 42: voltage sensor |
| 50: switch | 100: battery module (state |
| | of the art) |
| 110: battery cells | 111: positive electrode |
| 112: negative electrode | 113: vent |
| 114: cap assembly | 115: bus bar |
| 116: nut | 118: end plates |
| 118a: fastening portion | 130: housing |
| 131: support plate | 140: bolts |
| 170: heat exchange member | 411, 412, 413, 41n: current sensors |
| ARC, ARCT: region of an | |
| intensity of current as | |
| a function over the | |
| time domain | |
| ARCF: region of an intensity | |
| of current as a function | |
| over the frequency domain | |
| BP1, BP2, BPn: bandpass filters | CU: control unit |
| f: frequency | fᵢₙ, f_{fin}: frequency values |
| FB: filter bank | |
| I(t): intensity of current as | |
| function over the time domain | |
| I₀, I₁, I₂, Iₘₐₓ: values of | |
| the intensity of current | |
| Î(f): amplitude of the intensity | |
| of current as a function over | |
| the frequency domain (in a | |
| spectral representation) | |
| Î₁, Îₜₕᵣ, Î_{P}: amplitudes of | |
| the intensity of current | |
| S₁: current signal | S₂: voltage signal |
| Sᵢₙ: incoming operation signal | t: time |
| t₀, tₛ, t₁: points in time | t_{win}, t_{wfin}: points in time |
| T₁, T₂: terminals | x, y, z: axes of a Cartesian |
| | coordinate system |

What is claimed is:

1. A method for detecting a dielectric breakdown in a battery module, the method comprising:
measuring at least one operation state of the battery module;
generating at least one operation signal respectively corresponding to the at least one operation state;
checking whether the at least one operation signal comprises a pattern indicating a possible arc-fault within the battery module; and
generating a warning signal upon detecting the at least one operation signal comprises the pattern.

2. The method as claimed in claim 1, wherein the at least one operation state comprises a current generated by, or occurring in, the battery module,
wherein generating the at least one operation signal comprises generating a current signal based on the at least one operation state comprising the current, and
wherein checking whether the at least one operation signal comprises the pattern comprises checking whether the current signal comprises the pattern.

3. The method as claimed in claim 1, wherein the at least one operation state comprises a voltage generated by the battery module, or an electrical potential difference inside the battery module, and
wherein checking whether the at least one operation signal comprises the pattern indicating the possible arc-fault comprises checking whether the voltage signal comprises the pattern.

4. The method as claimed in claim 3, wherein checking whether the at least one operation signal comprises the pattern comprises:
generating a frequency spectrum for the at least one operation signal comprising a current signal and/or the voltage signal; and
comparing the frequency spectrum with a reference frequency spectrum.

5. The method as claimed in claim 4, wherein comparing the frequency spectrum with the reference frequency spectrum comprises detecting, for at least one frequency value in the reference frequency spectrum, whether an amplitude of the frequency spectrum exceeds an amplitude of the reference frequency spectrum, and
wherein generating the warning signal is based upon detection that the amplitude of the frequency spectrum exceeds the amplitude of the reference frequency spectrum at the at least one frequency value.

6. The method as claimed in claim 4, wherein generating the frequency spectrum comprises performing a Fourier transform of at least a part of the current signal and/or the voltage signal.

7. The method as claimed in claim 6, the method further comprising:
storing amplitudes of the at least one operation signal for sample points in time within a time window; and
performing a fast Fourier transform based on the sample points and the stored amplitudes.

8. The method as claimed in claim 2, wherein checking whether the at least one operation signal comprises the pattern comprises:
inputting the at least one operation signal to at least one bandpass filter;
measuring an amplitude of a signal outputted from the bandpass filter; and
comparing the amplitude of the signal outputted from the bandpass filter with a reference value, and
wherein the warning signal is based upon detecting the amplitude exceeds the reference value.

9. The method as claimed in claim 1, further comprising disconnecting the battery module from a load in response to the warning signal.

10. A battery system comprising:
a battery module comprising at least one battery cell;
a measurement device configured to measure at least one operation state of the battery module, and to generate at least one operation signal corresponding to the at least one operation state; and
a control unit configured to receive the at least one operation signal from the measurement device, check whether the at least one operation signal comprises a pattern indicating an occurrence of an arc-fault within the battery module, and generate a warning signal upon detection that the at least one operation signal comprises the pattern.

11. The battery system as claimed in claim 10, wherein the at least one operation state comprises a current generated by, or occurring in, the battery module,
wherein the measurement device comprises a current sensor configured to measure the current, and configured to generate a current signal corresponding to the current and the at least one operation signal, and
wherein the control unit is configured to check whether the current signal comprises the pattern.

12. The battery system as claimed in claim 10, wherein the at least one operation state comprises a voltage generated by, or an electrical potential difference inside, the battery module,
wherein the measurement device comprises a voltage sensor configured to measure the voltage, and configured to generate a voltage signal corresponding to the voltage corresponding to the at least one operation signal, and
wherein the control unit is configured to check whether the voltage signal comprises the pattern.

13. The battery system as claimed in claim 12, wherein the control unit is configured to generate a frequency spectrum of the at least one operation signal corresponding to a current signal or the voltage signal, and to compare the frequency spectrum with a reference frequency spectrum.

14. The battery system as claimed in claim 10, further comprising:
a first terminal connected via a first electrical line to the at least one battery cell;
a second terminal connected via a second electrical line to the at least one battery cell;
a first switch configured to interrupt the first electrical line upon receiving a first interruption signal; and
a second switch configured to interrupt the second electrical line upon receiving a second interruption signal,
wherein the control unit is configured to send the first interruption signal, and/or send the second interruption signal, based upon the warning signal.

15. A vehicle comprising the battery system as claimed in claim 10.
